(19) United States
(12) Patent Application Publication
(10) Pub. No.: US 2026/0357410 A1
(43) Pub. Date: Nov. 12, 2026

(54) VACUUM VAPOR DEPOSITION APPARATUS AND METHOD OF FABRICATING DEVICE USING SAME

(71) Applicant: KOREA ADVANCED NANO FAB CENTER, Suwon-si (KR)

(72) Inventors: Taek KIM, Seongnam-si (KR); Shin Keun KIM, Yongin-si (KR); Dong Hwan JUN, Yongin-si (KR); Chang Hwan KIM, Suwon-si (KR); Hae Yong JEONG, Yongin-si (KR); Woong Sun LIM, Suwon-si (KR); Gwan Yeol PARK, Suwon-si (KR); Eun Chong KANG, Suwon-si (KR)

(73) Assignee: KOREA ADVANCED NANO FAB CENTER, Suwon-si (KR)

(21) Appl. No.: 19/358,957

(22) Filed: Oct. 15, 2025

(30) Foreign Application Priority Data
May 7, 2025 (KR) 10-2025-0058734

(51) Int. Cl. C23C 14/24; C23C 14/50; C23C 14/54; H10N 60/01

(52) U.S. Cl. CPC C23C 14/24; C23C 14/50; C23C 14/54; H10N 60/0912

(57) ABSTRACT

A vacuum vapor deposition apparatus and a method of fabricating a device using the same are proposed, and the disclosed apparatus includes a source emitter configured to emit a source material in a vacuum chamber, an opening-defining member configured to be spaced apart from and positioned above the source emitter in a y-axis direction, have a surface thereof arranged parallel to an xz-plane along a z-axis and an x-axis perpendicular to the y-axis in a fundamental arrangement, and have an opening through which the source material passes, the opening having a structure extending in an x-axis direction or a z-axis direction, and a substrate holder configured to be positioned spaced apart from the source emitter, and be mounted with a substrate on which the source material passing through the opening is deposited to face downward.

### CROSS REFERENCE TO RELATED APPLICATION

The present application claims priority to Korean Patent Application No. 10-2025-0058734, filed May 7, 2025, the entire contents of which are incorporated herein for all purposes by this reference.

### BACKGROUND OF THE INVENTION

### Field of the Invention

The present disclosure relates to a deposition apparatus and a device fabrication technology and, more particularly, to a vacuum vapor deposition apparatus and a method of fabricating a device using the same.

A Korean national project supported by the Korean government associated with this invention is described below:
Project Unique Number 1711183984
Project Serial Number 2023M3H3A1059080
Government Department MSIT (Ministry of Science and ICT)
Specialized Institution for Project Management NRF (National Research Foundation of Korea)
Title of Research Business Development of Core Technology
Title of Project Infrastructure constructed with the common equipments for quantum devices fabrication with different systems
Supervising Institute KOREA ADVANCED NANO FAB CENTER
Research Period 2023 Feb. 7~2025 Dec. 31

### Description of the Related Art

In order for a quantum computer to achieve a practical level of computation, which is unable to be performed with a classical computer using the Von Neumann method, i.e., in order to secure quantum supremacy, at least several hundred to several thousand qubits (i.e., quantum bits) have to be integrated. In fact, some companies have presented roadmaps to achieve the integration of 1,121 qubits by year 2023, and in the long term, they plan to achieve the integration of one million qubit QPUs (quantum process units). In the case of superconductor qubits, which are currently the most technologically advanced, an integration density of 1,000 qubits or more has been achieved and is continuously developing.

Superconducting qubits are classified into charge qubits, phase qubits, flux qubits, etc. depending on their methods, and all of them use a Josephson device as their core active device. Among these qubits, devices evaluated to have the best performance, especially in terms of long coherence time, are the charge qubits. The charge qubits may be divided into transmon qubits and other charge qubits (i.e., general charge qubits) depending on the detailed design, and may be divided into fixed frequency qubits and tunable frequency qubits depending on the presence or absence of frequency control function controlled by the Josephson device in use. Fixed frequency transmons currently demonstrate best performance and achieve the integration of 1,000 qubits or more. Here, a frequency corresponds to a quantized energy gap of a superconducting qubit.

A charge qubit fabricated with a superconducting circuit is fundamentally formed by a capacitor and a Josephson device (a Josephson junction). The energy of the capacitor is interpreted as kinetic energy, and the energy of the Josephson device (the Josephson junction) is interpreted as potential energy. In a case where the total energy of a system, i.e., the Hamiltonian, is quantized, gaps between a plurality of energy levels occurring may be different from each other. Accordingly, the superconducting circuit including the Josephson device and the capacitor may be used as a qubit having anharmonicity. Among the discontinuous energy levels, the lowest ground state and the 1st excited state may be used as state 0 and state 1. In this case, the Hamiltonian Ĥ of the qubit may be given as in mathematical formula 1 below.

Ĥ=4E_{C}(\hat{n}−n_{g})²−E_{J} cos \hat{φ}

In the mathematical formula 1, charging energy E_{C}, Josephson energy E_{J}, a number operator \hat{n}, and offset charge ng may be respectively defined as in mathematical formulas 2 to 5 below.

$${E}_{c} = \frac{{e}^{2}}{2 C} \qquad [ Mathematical Formula 2 ]$$

$${E}_{J} = {I}_{c} \frac{ℏ}{2 e} = {I}_{c} \frac{{Φ}_{0}}{2 π} \qquad [ Mathematical Formula 3 ]$$

$$\hat{n} = \frac{{Q}_{J}}{2 e} \qquad [ Mathematical Formula 4 ]$$

$${n}_{g} = \frac{{C}_{Σ} {V}_{g}}{2 e} \qquad [ Mathematical Formula 5 ]$$

In the above mathematical formulas, C and Q (i.e., Q_{J}) are respectively capacitance and a quantity of charge, I_{C} is a critical current value of a Josephson junction, and Φ₀ is magnetic flux quanta. h is Dirac's constant and e is elementary charge. The magnetic flux quanta Φ₀ are given by a following mathematical formula 6.

$${Φ}_{0} = \frac{h}{2 e} \qquad [ Mathematical Formula 6 ]$$

In the mathematical formula 6, h is Planck's constant.

When an eigenvalue of energy (an energy level) is obtained by using the mathematical Formulas above, it is as shown in mathematical formula 7 below.

hω_{m,m+1}=\sqrt{8E_{C}E_{J}}−E_{C}(m+1)

Referring to the mathematical formula 7, an initial energy gap is determined by a root 8E_{C}E_{J} value \sqrt{8E_{c}Eⱼ}, and as an energy level increases thereafter, a value that is obtained by subtracting an integer multiple of an E_{C} value from \sqrt{8E_{c}Eⱼ} according to the energy level corresponds to an energy difference between two energy levels. In the mathematical formula 7, ω is an angular frequency and m is an integer.

From the above, it may be seen that the energy and anharmonicity of a qubit are determined by the combination of E_{C} and E_{J} values. In particular, it may be seen that the anharmonicity varies depending on the ratios of E_{C} and E_{J}, even when qubits have the same energy because energy values \sqrt{8E_{c}Eⱼ} are the same.

In the case of a general charge qubit, E_{C} and E_{J} are designed to have similar values, and in this case, anharmonicity becomes considerably large. However, when E_{C} and E_{J} are similar to each other, there is a problem that coherence life time becomes short due to the large influence of charge noise. In contrast, in the case of a transmon qubit, a ratio of E_{J}/E_{C} is determined to be about 30 to 50 or more, in which case there is an advantage in that it is hardly affected by charge noise and thus no offset charge n_{g} is required. However, anharmonicity is reduced, and when E_{C} and E_{J} values are not precisely controlled, there may still occur a problem that energy E_{0,1} for excitation from state 0 to state 1 may cause excitation from state 1 to state 2. A case where the energy for the excitation from the state 0 to the state 1 causes the excitation from the state 1 to the state 2 is called leakage.

Even if the anharmonicity is small, when only one qubit is controlled, the leakage may be prevented by precisely controlling a microwave signal. However, in QPUs and the like that require a plurality of qubits, there may be cases where a microwave signal for controlling a designated qubit controls an adjacent qubit. In particular, for example, when E_{0,1} (i.e., the energy for excitation from state 0 to state 1) of a first qubit is equal to E_{1,2} (i.e., the energy for excitation from state 1 to state 2) of a second qubit, a microwave signal controlling the first qubit may cause leakage of the second qubit.

In general, the energy of a qubit may be determined between about 4 GHz and 8 GHz in consideration of an operating temperature, dielectric loss, etc., and the anharmonicity of a transmon may be several hundred MHz, which is a few percent of the magnitude of the energy. As described above, given the anharmonicity that is only a few percent of the qubit energy, when energy of qubits has a few percent dispersion (error) due to process dispersion (error), various forms of frequency interference may occur between the qubits, so this may be called frequency collision or frequency crowding.

The dispersion of E_{C} and E_{J} values due to the process dispersion (error) may be an unavoidable problem, and among them, the dispersion of E_{J} values in particular may cause a problem. An E_{J} value may ultimately be determined by an I_{C} value, and the I_{C} value is given by the experimental Ambegaokar-Baratoff relation as follows:

$${I}_{C} = \frac{π}{2 e} \frac{Δ}{{R}_{n}} \qquad [ Mathematical Formula 8 ]$$

In the mathematical formula 8, Δ represents superconducting gap energy, and Rn (normal resistance) is a resistance value (i.e., a room temperature resistance value) of a Josephson junction measured at room temperature. Since Rn is the resistance value, it is determined by the structure of a Josephson device, such as a surface area of the Josephson junction and a thickness of an insulation film, and ultimately each E_{J} value may be determined accordingly. The dispersion of the E_{C} values may also affect change in device properties, but in the case of the transmon, capacitance is designed to be large, so E_{J} dispersion may play a more decisive role than the E_{C} dispersion.

An E_{J} depends on an I_{C} value, and the I_{C} value may be determined by an Rn value. The Rn value may be determined by the structures of a Josephson device, i.e., a surface area, a thickness, etc. of an insulation film. Accordingly, in fabricating the Josephson device, it is required to reduce the process error and implement a junction surface (i.e., a Josephson junction surface) of precise size.

A Josephson device is typically fabricated by a process known as the Dolan process or the Manhattan process, both of which involve deposition of superconducting metal by angle evaporation conducted twice in directions different from each other.

To exemplify the Dolan process, first, as illustrated in FIG. 1, when two photoresists, i.e., first and second photoresists 110 and 120 whose sensitivities are different to e-beam lithography, are sequentially formed on a substrate 100 and then exposure and development are performed, the first photoresist 110 at the bottom is more developed and removed, thereby creating a cross-sectional profile having an undercut generated. By using such a photoresist pattern, the substrate 100 is tilted at a specific angle as illustrated in FIG. 2, so that a first metal film 130 (e.g., an Al film) for fabricating a Josephson device is deposited, oxygen is introduced and a surface part of the first metal film 130 is oxidized to form an oxide film 140 (e.g., an Al oxide film) having a predetermined thickness, and then the substrate 100 is tilted in a direction different from the direction of the time when the first metal film 130 is formed, whereby a second metal film 150 (e.g., an Al film) may be deposited. After going through such a process, a Josephson device may be formed in which the first metal film 130 and the second metal film 150 only partially overlap each other and an insulator, i.e., an oxide film 140, is positioned therebetween. A Josephson junction is defined in an area where the first metal film 130 and the second metal film 150 overlap each other. For convenience of description, the first photoresist 110 in FIG. 1 is not illustrated in FIG. 2.

In such a type of fabrication method, not only the size and height of each photoresist but also a deposition incidence angle of a metal are important factors that determine the size of the device being fabricated. However, due to the current equipment structure of an e-beam evaporator equipment, the method of depositing a material on an inclined surface has one problem that the thickness of the deposited metal varies depending on the positions of a substrate, and as a bigger problem, the incidence angle of the deposited metal varies depending on the positions of the substrate. The process using the conventional e-beam evaporator generally rotates a substrate in both a rotational manner and an orbital manner in order to deposit a uniform thin film. However, since such rotation is unable to be used in fabricating a Josephson device, the problems described above may be unavoidable.

Referring to FIG. 3, when a metal source generation unit with parts 200 and 300 is assumed to be a rough point light source, since the amount of flux 400 of a source material has symmetry with respect to a center line, it may be said that processing is carried out while the same amount of metal evaporates onto both sides with respect to the center line. Here, the reference numeral 200 represents a crucible containing the metal source material, and the reference numeral 300 represents a crucible holder having an e-beam gun. Meanwhile, when the substrate 100 is positioned at an inclined angle, cross-sectional areas become different from each other for parts positioned on the left and right sides of the substrate 100, so one half of the substrate 100 (i.e., the right half in FIG. 3) receives more flux 400 than the other half (i.e., the left half in FIG. 3), thereby resulting in the metal deposited in a thicker thickness. As one method for overcoming such a problem, a method such as that in the related document 1 (WO 2022/067433 A1) has been proposed.

The second problem is that in a case where deposition is performed while a substrate is positioned at an inclined angle, an incidence angle of a metal source material to be deposited varies depending on the positions of the substrate. When the incidence angle of the metal source material changes depending on the positions of the substrate, the length and width of a metal pattern to be deposited changes depending on the positions of the substrate. Accordingly, the length and width of a Josephson device (a Josephson junction) change depending on the positions on the substrate. Although such deviation decreases as a distance between the metal source generation unit and the substrate increases, the greater the distance, the more severe the waste of the source becomes and the more the cost of maintaining the vacuum of a deposition chamber increases significantly. As a method for overcoming the problem described above, the related document 2 (Wafer-scale uniformity improvement of Dolan bridge Josephson junction by shadow evaporation bias correction, arXiv.2403.01894) proposes a method of correcting Josephson devices so as to be fabricated to have a required size or the same size thereof by setting the design size of the Josephson devices differently for each position on a substrate. However, in the case of the pattern correction method, there is a problem that a pattern size should be corrected individually according to each position of the substrate, and the correction has to be performed every time the position or size of each device changes.

### SUMMARY OF THE INVENTION

An objective of the present disclosure for solving the technical problems is to provide a vacuum vapor deposition apparatus for enabling fabrication of a device having a more accurate and precise size by reducing errors (dispersion), which occur depending on the positions of a substrate, in the fabrication of quantum technology-related devices such as Josephson devices.

In addition, another objective of the present disclosure for solving the technical problems is to provide a method of fabricating a device by using the above-described vacuum vapor deposition apparatus.

The problems to be solved by the present disclosure are not limited to the problems mentioned above, and other problems not mentioned herein may be understood by those skilled in the art from the description below.

According to one exemplary embodiment of the present disclosure, there is provided a vacuum vapor deposition apparatus using an evaporation method, the apparatus including: a source emitter configured to emit a source material through evaporation in a vacuum chamber; an opening-defining member configured to be spaced apart from and positioned above the source emitter in a y-axis direction within the vacuum chamber, have a surface thereof arranged parallel to an xz-plane along a z-axis and an x-axis perpendicular to the y-axis in a fundamental arrangement, and have an opening through which the source material passes, the opening having a structure extending in an x-axis direction or a z-axis direction in the fundamental arrangement; and a substrate holder configured to be positioned spaced apart from the source emitter with the opening-defining member interposed therebetween within the vacuum chamber, and be provided with a substrate mounted thereon so as to allow a surface of the substrate on which the source material passing through the opening is deposited to face downward, wherein the substrate holder may be configured to be movable along at least one of a first parallel direction parallel to the substrate and a second parallel direction parallel to the substrate and perpendicular to the first parallel direction, the first parallel direction may be parallel to the z-axis and the second parallel direction may be parallel to the x-axis in the fundamental arrangement, and the substrate holder and the opening-defining member may be configured to be rotatable around the z-axis.

A center of the source emitter and a center of the opening may be arranged on a vertical line.

The substrate holder may be configured to be rotatable at a controlled angle in each of a first rotational direction and a second rotational direction opposite to the first rotational direction around the z-axis.

The opening may have a slit shape.

The opening may be configured to extend in the x-axis direction and have a length along the x-axis and a width along the z-axis, and the substrate holder may be configured to be linearly movable along at least the first parallel direction.

The opening may be configured to extend in the z-axis direction and have a length along the z-axis and a width along the x-axis, and the substrate holder may be configured to be linearly movable along at least the second parallel direction.

The opening may have a length along any one of the x-axis and the z-axis and a width along the other of the x-axis and the z-axis, and a width of the opening may be in a range of 0.1 to 10 cm.

The vacuum vapor deposition apparatus may be configured to variably control a width of the opening.

A center of the substrate, the center of the opening, and the center of the source emitter may be arranged on a vertical line when the center of the substrate is positioned on the center of the opening.

The apparatus may further include a shutter member arranged between the source emitter and the opening-defining member and configured to block or allow movement of the source material toward the opening-defining member, or control the movement in other methods.

The apparatus may further include a mechanical component unit to which the substrate holder and the opening-defining member are connected or coupled, wherein the mechanical component unit may be configured to be able to move the substrate holder along at least one of the first and second parallel directions, and may be configured to be able to rotate the substrate holder and the opening-defining member around the z-axis.

The apparatus may further include first and second mechanical component units to which the substrate holder and the opening-defining member are connected or coupled, wherein the substrate holder and the opening-defining member may be arranged between the first and second mechanical component units, and the first and second mechanical component units may be configured to be able to move the substrate holder along at least one of the first and second parallel directions and are configured to be able to rotate the substrate holder and the opening-defining member around the z-axis.

The apparatus may further include a support member configured to directly or indirectly support the substrate holder on a side opposite to a side where the opening-defining member is arranged.

The opening-defining member may be configured to have a function of a gas injection unit for injecting gas into the vacuum chamber.

The vacuum vapor deposition apparatus may be configured to perform a deposition process while the substrate holder is rotated by a given angle around the z-axis.

The vacuum vapor deposition apparatus may be configured to perform a deposition process over an entire effective region of the substrate surface while continuously moving the substrate holder at a given speed.

The vacuum vapor deposition apparatus may be configured to perform a deposition process on an entire effective region of the substrate surface in a step-and-repeat manner, so as to move the substrate holder after performing the deposition process on an N-th region of the substrate surface and perform the deposition process on an (N+1)-th region of the substrate surface in the step-and-repeat manner.

According to another exemplary embodiment of the present disclosure, there is provided a method of fabricating a device, the method including depositing a material film by using a vacuum vapor deposition apparatus as described above.

The device may include a Josephson device.

The method may further include forming a first superconducting material film on a substrate while a substrate holder and an opening-defining member are rotated at a first angle condition around a z-axis; forming an insulation film on a surface of the first superconducting material film; and forming a second superconducting material film on the insulation film while the substrate holder and the opening-defining member are rotated a second angle condition different from the first angle condition around the z-axis.

In each of the forming of the first superconducting material film and the forming of the second superconducting material film, the substrate holder may be moved along at least one of first and second parallel directions.

According to the exemplary embodiments of the present disclosure, it is possible to implement the vacuum vapor deposition apparatus for enabling fabrication of a device having a more accurate and precise size by reducing errors (dispersion), which occur depending on the positions of a substrate, in the fabrication of quantum technology-related devices such as Josephson devices. In addition, according to one exemplary embodiment of the present disclosure, the method of fabricating the device by using the above-described vacuum vapor deposition apparatus may be implemented.

A conventional evaporator has a fundamental limitation in that an amount of metal deposited and an incidence angle vary depending on the positions of a substrate due to the properties of a source being carried out and deposited radially (partially radially) at a predetermined angle from a metal source generation unit having a relatively small cross-sectional area. Among these limitations, the problem of varying the amount of metal may be partially alleviated by the related document 1, but the bigger problem of varying the incidence angle has not been resolved at the equipment level, so the method of correcting the pattern of a substrate has been proposed in the related document 2. However, in the case of the pattern correction method, there is a problem that a pattern size has to be corrected individually according to a position of the substrate, and the correction has to be performed every time the position or size of each device changes.

According to one exemplary embodiment of the present disclosure, a vacuum vapor deposition apparatus and a related method thereof capable of drastically reducing process error (dispersion) may be implemented, for example, by using an opening-defining member having a defined opening in the shape of a slit so as to allow a source material to pass only through the opening, and by making an incident amount and incidence angle of the source material to be uniform or nearly uniform over the entire effective region of a substrate while moving the position of the substrate on which a predetermined mask pattern is formed.

In addition, according to one exemplary embodiment of the present disclosure, since the distance between the source emitter and the substrate may be reduced, source overconsumption that occurs when the deposition is performed only through the opening may be compensated for. In addition, as the equipment size is reduced, an effect may be obtained that reduces the equipment fabricating cost and the operating cost such as a vacuum maintenance cost.

However, the effects of the present disclosure are not limited to the effects, and may be variously expanded within a range that does not depart from the technical spirit and scope of the present disclosure.

### BRIEF DESCRIPTION OF THE DRAWINGS

FIG. 1 is a cross-sectional view illustrating a formation process of a photoresist pattern according to a Dolan process, which is one of methods for fabricating a Josephson junction.

FIG. 2 includes cross-sectional views (A) to (C) each illustrating a double angle evaporation process using a photoresist pattern having Dolan bridges.

FIG. 3 is a view illustrating a problem that a thickness of a deposited metal varies depending on positions of a substrate in angle evaporation.

FIGS. 4 and 5 are views that serve as the fundamental background of one exemplary embodiment of the present disclosure and illustrate how an incidence angle of a deposited source material changes depending on positions of a tilted substrate.

FIG. 6 is a view related to one exemplary embodiment of the present disclosure and exemplarily illustrating a fabricating process of a Josephson device.

FIGS. 7 and 8 are views that serve as the fundamental background of one exemplary embodiment of the present disclosure and illustrate how an incidence angle of a deposited source material changes depending on positions of a tilted substrate.

FIG. 9 is a view illustrating that a width of a Josephson device changes depending on the positions illustrated in FIGS. 7 and 8.

FIG. 10 is a view exemplarily illustrating the change in a width of a Josephson junction along a z-axis direction of a substrate.

FIG. 11 is a view illustrating a vacuum vapor deposition apparatus using an evaporation method according to one exemplary embodiment of the present disclosure.

FIGS. 12 and 13 are views illustrating some enlarged components of the vacuum vapor deposition apparatus in FIG. 11.

FIG. 14 is a plan view exemplarily illustrating an opening-vacuum vapor deposition defining member applicable to the apparatus according to one exemplary embodiment of the present disclosure.

FIG. 15 is a plan view exemplarily illustrating an opening-defining member applicable to the vacuum vapor deposition apparatus according to another exemplary embodiment of the present disclosure.

FIG. 16 is a view illustrating a vacuum vapor deposition apparatus using an evaporation method according to another exemplary embodiment of the present disclosure.

FIGS. 17A to 17C are cross-sectional views illustrating a method of fabricating a device by using a vacuum vapor deposition apparatus using an evaporation method according to one exemplary embodiment of the present disclosure.

### DETAILED DESCRIPTION OF THE INVENTION

Hereinafter, exemplary embodiments of the present disclosure will be described in detail with reference to the attached drawings.

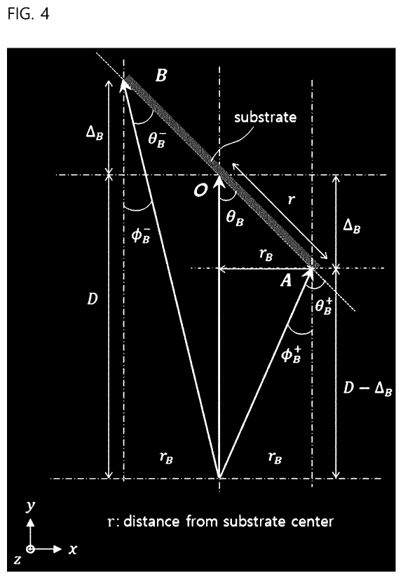

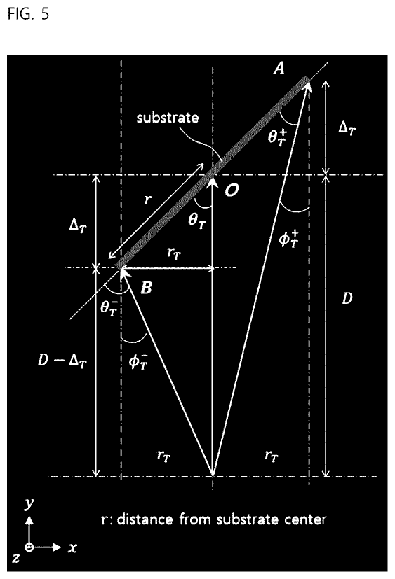

FIGS. 4 and 5 are views that serve as the fundamental background of one exemplary embodiment of the present disclosure and illustrate how an incidence angle of a deposited source material (metal) changes depending on positions of a tilted substrate. FIGS. 4 and 5 are views illustrating calculation of the incidence angle of the source material (metal) at a position that is r distance away from the center of the substrate along a slope in deposition of a first metal film (a bottom metal) and deposition of a second metal film (a top metal). FIG. 4 is a view illustrating that the incidence angle at which the deposition is performed varies depending on positions of the substrate in bottom metal angle evaporation, and FIG. 5 is a view illustrating that the incidence angle at which the deposition is performed varies depending on the positions of the substrate in top metal angle evaporation.

Referring to FIGS. 4 and 5, even when the center of the substrate is arranged so as to have a required deposition incidence angle, the incidence angle gradually increases at a lower position in the center, and conversely, the incidence angle gradually decreases at a higher position in the center.

When angles of the metal incident on the center of the substrate and on both ends of an x-axis are calculated, under given conditions that a diameter of the substrate is approximately 20 cm (8 inch substrate), an incidence angle at the center of the substrate is 45°, and distances between the center of the substrate and the metal source generation unit are 30 cm, 100 cm, and 150 cm, the incidence angle at the center does not change, but incidence angles on the both ends corresponding to the distances are respectively 62° and 34°, 48.3° and 41.3°, and 47.8° and 42.4°. Although a deviation in the incidence angles decreases as the distance between the source generation unit and the substrate increases, it may be seen that a large angular deviation exists even at the distance of 150 cm. If this distance is increased further, a deviation will decrease further, but the rate of decrease will decrease, and as the distance increases, the size of a chamber will increase, so there may be an accompanied problem that the cost and time of creating a vacuum will increase accordingly. Such deviation in incidence angle may cause the length of a Josephson device to vary by approximately 1 to 3% or more for each substrate position, depending on the size of the substrate.

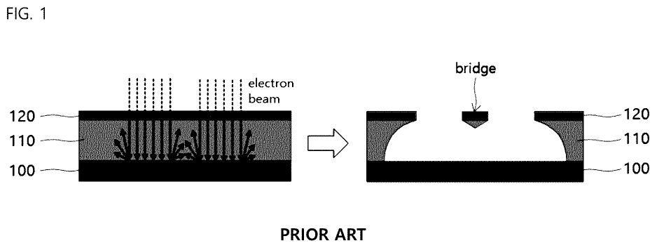

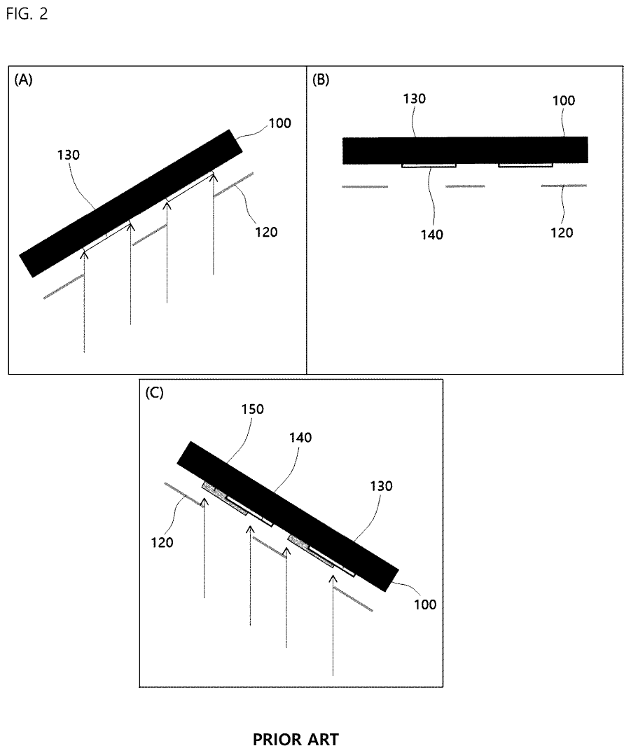

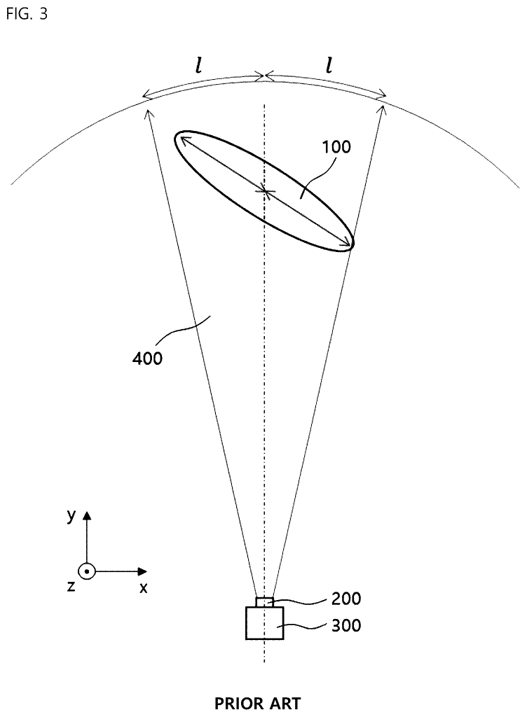

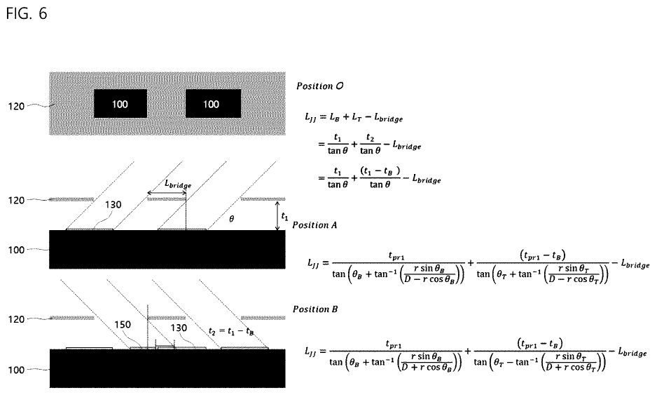

FIG. 6 is a view related to one exemplary embodiment of the present disclosure and exemplarily illustrating a fabricating process of a Josephson device. Here, the reference numerals may be the same as those described in FIGS. 1 and 2. Of the three views in FIG. 6, the top view is a plan view, and the bottom two views are cross-sectional views. For convenience of description, a first photoresist and an insulation film (e.g., an oxide film) are not illustrated in FIG. 6. FIG. 6 is for illustrating a phenomenon in which the length of a Josephson junction fabricated varies depending on positions in a case where incidence angles are different depending on the positions of a substrate. In FIG. 6, “Position O” corresponds to the center of the substrate, and “Position A” and “Position B” correspond to the positions A and B in FIGS. 4 and 5.

Referring to FIG. 6, a length L_{JJ} of the Josephson junction may be obtained by subtracting a length L_{bridge} of a photoresist bridge from the sum of lengths of a first metal film (i.e., the bottom metal) 130, which is defined as a length from one end of a deposited metal to an end of the photoresist bridge, and a second metal film (i.e., the top metal) 150, that is, from the sum of L_{T} and L_{B}. Meanwhile, L_{B} and L_{T} vary depending on angles of metal deposition, so when an incidence angle varies depending on positions of the substrate, the length of the Josephson junction fabricated will vary depending on the positions of the substrate, thereby meaning that a frequency of a fabricated qubit will vary.

For example, under given conditions that a thickness tₚᵣ₁ of the first photoresist is 400 nm, a length L_{bridge} of the photoresist bridge is 400 nm, a thickness t_{B} of the first metal film 130 is 50 nm, and a distance between a metal source generation unit and the center of the substrate is 80 cm, in a case where an incidence angle at the center of the substrate 100 is set to 45°, an incidence angle at a low point (a low end) that is 7.5 cm away from the center of the substrate 100 becomes 48.3°, and an incidence angle at a high point (a high end) that is 7.5 cm away from the center of the substrate 100 becomes 41.3°.

When the length Lys of the Josephson junction is obtained by referring to the views and mathematical formulas exemplified in FIG. 6, an L_{JJ} at the center of the substrate is 350 nm, while an L_{JJ} at the low point 15 cm away from the center and an L_{JJ} at the high point 15 cm away from the center are respectively 345 nm and 358 nm, thereby resulting in deviations of −1.4% and 2.3%, respectively. Such calculations correspond to a case where the substrate is rotated so that the lower and higher points of the substrate are swapped during deposition of the first metal film (the bottom metal) and the second metal film (the top metal). In a case where the substrate is rotated so that the lower side of the substrate during the deposition of the first metal film (the bottom metal) is also positioned toward the lower side during the deposition of the second metal film (the top metal), deviations of Lu become 20 to 25% or more.

Meanwhile, change in the width of the Josephson junction depending on the positions of the substrate may be more severe.

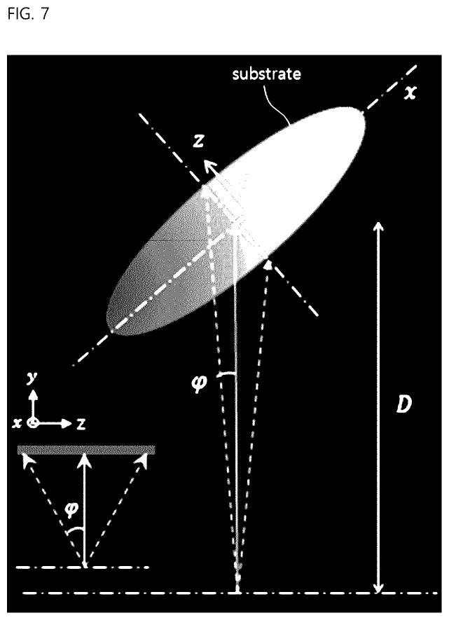

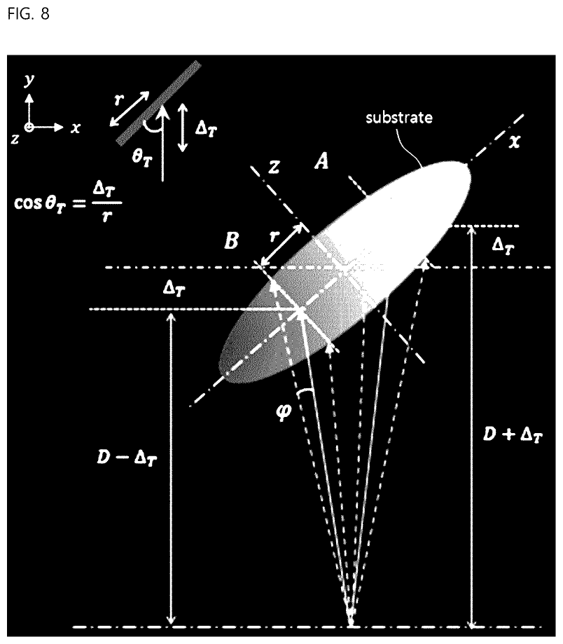

FIGS. 7 and 8 are views that serve as the fundamental background of one exemplary embodiment of the present disclosure and illustrate how an incidence angle of a deposited source material (metal) changes depending on positions of a tilted substrate. FIGS. 7 and 8 illustrate views for calculating metal incidence angles according to the positions of the substrate in a z-axis direction. FIG. 7 is the view illustrating that an incidence angle of deposition in the z-axis direction changes depending on positions in the z-axis direction from the center of the substrate, and FIG. 8 is the view illustrating that an incidence angle of deposition in the z-axis direction changes depending on positions in the z-axis direction from positions away from the center of the substrate in the x-axis direction.

Referring to FIGS. 7 and 8, a deviation occurs in each incidence angle in the z-axis direction of the substrate. This deviation acts complexly depending on the x-axis positions, and such a deviation changes the width of a Josephson device. The change in the width of such a Josephson device is as high as approximately 7.3% or more in a case where a distance between the source generation unit and the center of the substrate is 80 cm, even on an approximate 15 cm substrate, thereby limiting normal device fabrication.

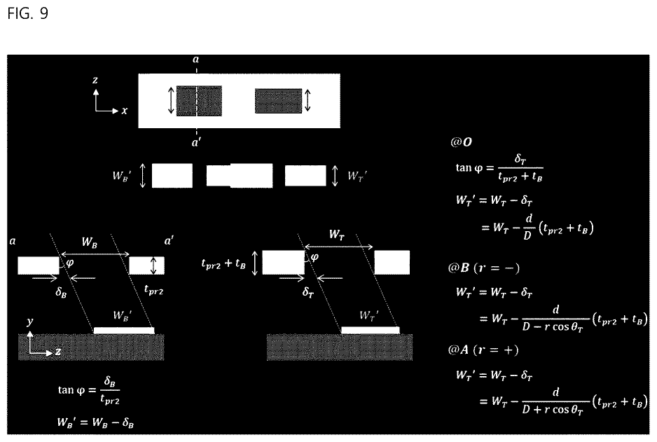

FIG. 9 includes views illustrating that a width of a Josephson device changes depending on the positions illustrated in FIGS. 7 and 8. Of the four views in FIG. 9, the upper two views are plan views, and the lower two views are cross-sectional views. FIG. 9 illustrates the views for calculating a width of a Josephson junction according to an incidence angle. The width of the Josephson junction varies not only with the positions in the z-axis direction but also with the positions in the x-axis direction.

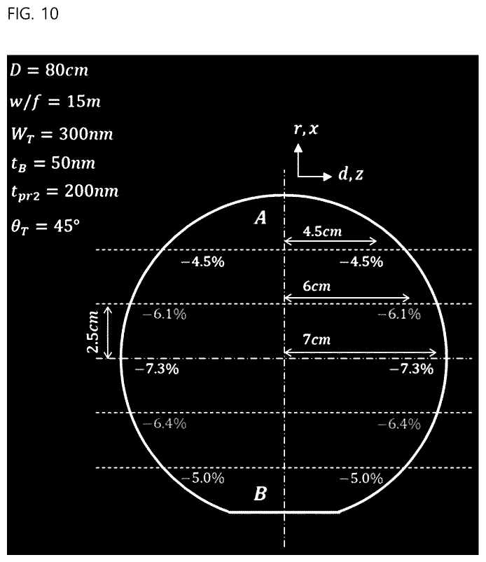

FIG. 10 is a view exemplarily illustrating change in a width of a Josephson junction along a z-axis direction of a substrate. As can be seen in FIG. 10, at the center of a substrate where an incidence angle of a metal source in a z-axis direction is vertical, the Josephson junction is formed with a width of 300 nm, which is the as-is width of a photoresist pattern, but as a position moves away from the z-axis direction, a change in the width of about −7.3% or more may occur. Such a deviation may be reduced as a distance between a metal source generation unit and the substrate increases, but as the distance increases, not only does the waste of the source increase, but the cost of maintaining a vacuum in a deposition chamber also increases significantly. However, the degree of width change illustrated in FIG. 10 is presented as an example under given specific conditions and may vary depending on conditions.

A qubit using a superconducting circuit may include a Josephson device (a Josephson junction). The properties of the qubit may be greatly affected by the properties of the Josephson device (the Josephson junction). For example, in the case of a transmon, an energy gap of the qubit may be determined by an E_{J} value of a Josephson device, and also anharmonicity may be determined. The E_{J} value may be determined by the size of the Josephson device and the thickness of an insulation film, and the device size may be greatly affected not only by the size of a photoresist pattern but also by the angle of metal deposition (i.e., an incidence angle of a source). A problem may arise when a deposition angle varies depending on the positions of a substrate due to limitations in the conventional metal deposition method. For a 6-inch substrate, a width deviation of a Josephson device may be as high as 7.3% or more, and the deviation may further increase as the size of the substrate increases. Considering that a typical quantum computer requires a frequency deviation in a range of about 1 to 28, the above-described dimensional deviation (i.e., the width deviation) is a very large deviation that may limit the implementation and operation of a normal quantum computer.

In one exemplary embodiment of the present disclosure, there may be provided a deposition apparatus and a related method thereof for uniform or accurate (precise) fabrication of a superconducting Josephson device as an example. In particular, in one exemplary embodiment of the present disclosure, there may be provided a deposition apparatus and a related method thereof for ensuring uniformity and/or precision of the size of a Josephson junction, which is essential for accurately controlling the frequency of a qubit, in fabricating a superconducting quantum qubit having a fixed frequency structure and a quantum process unit (QPU) using the same.

In one exemplary embodiment of the present disclosure, a technology/method may be provided that may significantly reduce a change in a deposition angle depending on positions of a substrate not only by installing an opening-defining member (a kind of screen) having an opening that is open in the shape of a slit in the center thereof, as an example, in front of an inclined substrate but also by performing deposition while moving the substrate. For example, in the deposition apparatus using the evaporation method, in a case where the opening-defining member (the screen) having a predetermined opening is installed on the front side of a substrate and deposition is allowed to occur only through the opening while the substrate is moved in a predetermined manner, it is possible to implement a device and a method thereof, in which a source material (e.g., metal) is deposited at a uniform (or nearly uniform) incidence angle. In this case, the deposition may be performed in a step-and-repeat manner in which unit deposition is performed for a required thickness and then a substrate is moved, or in a continuous deposition manner in which deposition is performed continuously while moving a substrate tilted at a predetermined angle. Typically, the size of a Josephson device is less than or equal to a few hundred nm and a size of a qubit is, for example, about 0.5 cm to 1 cm, so when the width of an opening is determined in a range of about 0.5 to 3 cm, a size of a very uniform Josephson junction may be obtained. The method according to one exemplary embodiment of the present disclosure may not only increase the uniformity of incidence angle of a deposited metal, but also improve the uniformity of thickness of the deposited metal.

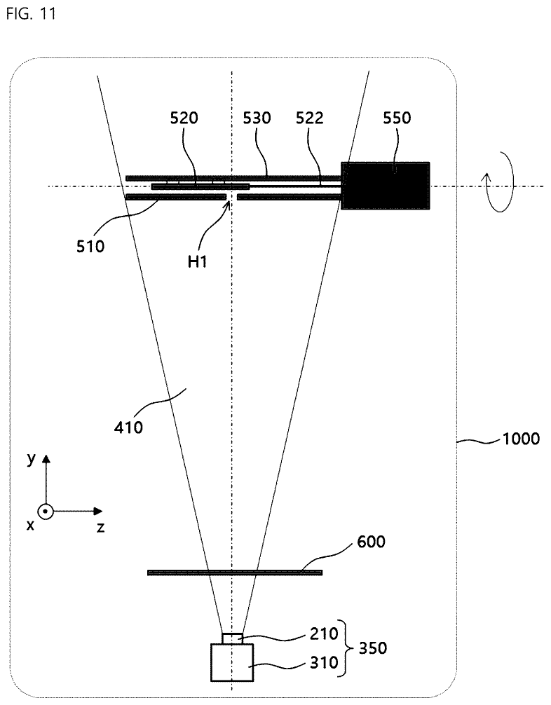

FIG. 11 is a view illustrating a vacuum vapor deposition apparatus using an evaporation method according to one exemplary embodiment of the present disclosure.

Referring to FIG. 11, the vacuum vapor deposition apparatus using the evaporation method according to one exemplary embodiment of the present disclosure may include a source emitter 350 for emitting a source material through evaporation within a vacuum chamber 1000. The source emitter 350 may include a source container 210 containing the source material and a source container holder 310 for holding this source container 210. The source container holder 310 may include an e-beam gun or other heating unit. The source material may be, for example, a metallic material. The source emitter 350 may be a kind of evaporator unit, and the evaporator unit may be an e-beam evaporator unit or a thermal evaporator unit. Reference numeral 410 represents a flux of the source material. The flux 410 may include a vaporized source material, i.e., an evaporated source material.

The vacuum vapor deposition apparatus may include an opening-defining member (or an aperture-defining member) 510 positioned above and spaced apart in a y-axis direction (a height direction) with respect to a source emitter 350 within a vacuum chamber 1000. In a fundamental arrangement, the opening-defining member 510 may be arranged in which its surface is parallel to an xz-plane along an x-axis perpendicular to a y-axis and a z-axis. The opening-defining member 510 may have an opening H1 through which a source material passes, and in the fundamental arrangement, the opening H1 may have a structure extending in an x-axis direction or a z-axis direction. The opening-defining member 510 may be referred to as a screen in which the opening H1 is formed. The opening-defining member 510 may have a thin plate shape.

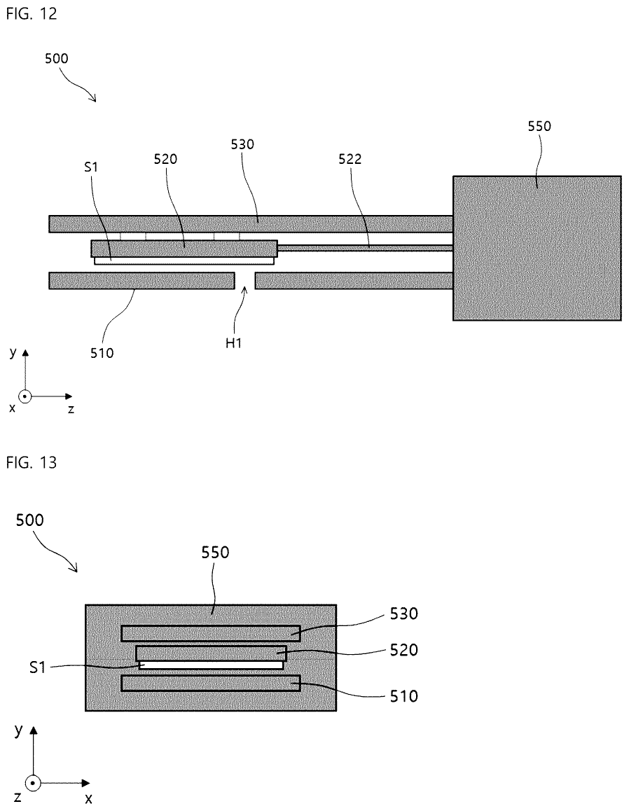

The vacuum vapor deposition apparatus may include a substrate holder 520 positioned spaced apart from the source emitter 350 with the opening-defining member 510 interposed therebetween within the vacuum chamber 1000. The substrate (S1 of FIG. 12) may be mounted on the substrate holder 520. The substrate may be mounted on the substrate holder 520 so as to allow the surface of the substrate, on which the source material passing through the opening H1 is deposited, to face downward. The substrate for material deposition may be mounted on a lower surface of the substrate holder 520.

The substrate holder 520 may be configured to be movable along at least one of a first parallel direction parallel to the substrate parallel direction parallel to the substrate and perpendicular to the first parallel direction. In the fundamental arrangement, the first parallel direction may be parallel to the z-axis, and the second parallel direction may be parallel to the x-axis. In other words, while in the arrangement state as illustrated in FIG. 11, the first parallel direction may be parallel to the z-axis, and the second parallel direction may be parallel to the x-axis. The substrate mounted on the substrate holder 520 may be moved along the at least one of the first and second parallel directions.

In addition, the substrate holder 520 and the opening-defining member 510 may be configured to be rotatable around the z-axis. The substrate holder 520 and the opening-defining member 510 may be rotatable in a first rotational direction and a second rotational direction opposite to the first rotational direction around the z-axis. The substrate holder 520 may be configured to be rotatable at a controlled angle in each of the first rotational direction and the second rotational direction around the z-axis. For example, the substrate holder 520 may be configured to be rotatable by about 90° in each of the first and second rotational directions around the z-axis. One of the first and second rotation directions may be clockwise, and the other may be counterclockwise. The substrate holder 520 and the opening-defining member 510 may rotate together to have the same or nearly the same inclined angle with respect to a horizontal plane. The substrate mounted on the substrate holder 520 may rotate together with the substrate holder 520.

The source material emitted by the source emitter 350, i.e., the vaporized source material, may reach the surface of the substrate mounted on the substrate holder 520 through the opening H1 so as to be deposited. During the material deposition process on the substrate, the substrate holder 520 may be moved in a predetermined direction. In addition, the vacuum vapor deposition apparatus may be configured to perform the deposition process in a state where the substrate holder 520 is rotated by a given angle around the z-axis.

According to one exemplary embodiment, the center of the source emitter 350 and the center of the opening H1 may be arranged on a vertical line. The opening H1 may have, for example, a slit shape. The opening H1 may extend in the x-axis direction and have a length along the x-axis and a width along the z-axis. Here, the length may be greater than or equal to the width. In the case where the opening H1 has the slit shape extending in the x-axis direction, the substrate holder 520 may be configured to be linearly movable at least along the first parallel direction. In the arrangement state illustrated in FIG. 11, the substrate holder 520 may be movable linearly at least along the z-axis direction.

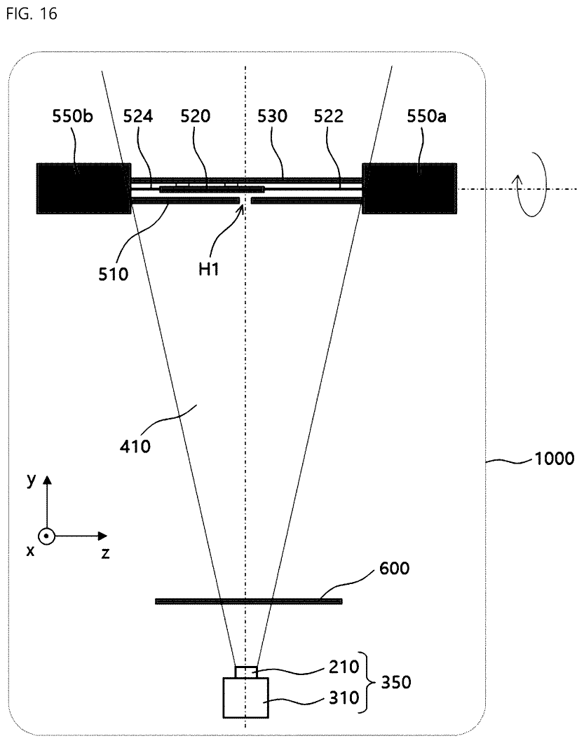

In another case, the opening H1 may extend in the z-axis direction and may have a length along the z-axis and a width along the x-axis. Here, the length may be greater than or equal to the width. In the case where the opening H1 has a slit shape extending in the z-axis direction, the substrate holder 520 may be configured to be linearly movable at least along the second parallel direction. This case will be described in more detail below with reference to FIG. 15.

The opening H1 may have a length along one of the x-axis and the z-axis and a width along the other of the x-axis and the z-axis, and the width of the opening H1 may be in a range of about 0.1 to 10 cm. The width of the opening H1 may be determined, for example, within a range of about 0.5 to 3 cm or within a range of about 0.5 to 1.5 cm, but is not limited thereto. In some cases, the vacuum vapor deposition apparatus may be configured to variably control the width of the opening H1. It may be possible to variably control the width of the opening H1 mechanically. The length of the opening H1 may be a length that allows deposition to be performed over part or all of the diameter of the substrate. The length of the opening H1 may be set to about 80% or more or about 90% or more of the diameter (the width) of the substrate so that the deposition may be performed over the entire effective region (the effective surface region) of the substrate. In this case, it may be advantageous to perform the deposition over the entire effective region (the effective surface region) of the substrate while performing a single linear movement motion (a movement motion of the substrate). However, in some cases, the length of the opening H1 may be set to less than 80% of the diameter (the width) of the substrate.

According to one exemplary embodiment, in performing deposition while the substrate is moved, the center of the substrate, the center of the opening H1, and the center of the source emitter 350 may be arranged on a vertical line when the center of the substrate is positioned on the center of the opening H1. Here, the center of the source emitter 350 may mean the emission center of the source container 210.

The vacuum vapor deposition apparatus may further include a mechanical component unit 550 to which the substrate holder 520 and the opening-defining member 510 are connected or coupled. The mechanical component unit 550 may be configured to be able to move the substrate holder 520 along at least one of the first and second parallel directions. In addition, the mechanical component unit 550 may be configured to be able to rotate the substrate holder 520 and the opening-defining member 510 around the z-axis. The mechanical component unit 550 itself may also rotate around the z-axis. The mechanical component unit 550 may include a mechanical movement component. For example, the mechanical component unit 550 may include at least one of a linear actuator and a rotary (rotation) actuator. A connection member 522 may be further provided between the substrate holder 520 and the mechanical component unit 550 to connect them. The connection member 522 may have, for example, a rod shape or a plate shape, or may have other shapes.

In addition, the vacuum vapor deposition apparatus may further include a support member 530 for directly or indirectly supporting the substrate holder 520 at a side opposite to a side where the opening-defining member 510 is arranged. The substrate holder 520 may be arranged between the support member 530 and the opening-defining member 510. The support member 530 may include, for example, at least one of structures in shapes such as a plate, a bar, or a rod. The support member 530 may support the substrate holder 520 at the rear side of the substrate holder 520. Accordingly, the movement of the substrate holder 520 may be more stably achieved by the support member 530. Between the substrate holder 520 and the support member 530, as a non-limiting example, a rail member, etc. may be arranged. The support member 530 may be rotated around the z-axis together with the substrate holder 520 and the opening-defining member 510. In addition, the support member 530 may be connected or coupled to the mechanical component unit 550.

Additionally, in some cases, the opening-defining member 510 may be configured to have a function of a gas injection unit for injecting gas into the vacuum chamber 1000. In this case, the opening-defining member 510 may include at least one gas injection passage for injecting oxygen gas, and the oxygen gas may be injected into the vacuum chamber 1000 through the at least one gas injection passage. At this time, the oxygen gas may be used to form an oxide film (an insulation film). In the case where the opening-defining member 510 is configured to have the function of the gas injection unit, a predetermined gas may be easily injected into a region adjacent to the substrate through the opening-defining member 510, so processes such as oxidation may be performed more easily. However, it may be optional for the opening-defining member 510 to have the function of the gas injection unit.

In addition, the vacuum vapor deposition apparatus may further include a shutter member 600 arranged between the source emitter 350 and the opening-defining member 510. The shutter member 600 may serve to block or allow the movement of the source material toward the opening-defining member 510, or control the movement of the source material in a different way. The shutter member 600 may be referred to as a global shutter. By using the shutter member 600, for example, ON/OFF of the deposition process may be controlled. Although not shown, the vacuum vapor deposition apparatus may further be provided to include: an ion milling part for cleaning the surface of the substrate; an ultraviolet (UV) lamp required for oxidation; oxygen supply equipment; other sensors; and the like.

According to one exemplary embodiment, the vacuum vapor deposition apparatus may be configured to perform the deposition process over the entire effective region of the substrate surface in a step-and-repeat manner. In this case, in the step-and-repeat method, after performing the deposition process for an N-th region of the substrate surface, the substrate holder 520 may be moved to a predetermined degree, and then the deposition process for an (N+1)-th region of the substrate surface may be performed, so that this process may be repeated. According to another exemplary embodiment, a vacuum vapor deposition apparatus may be configured to perform a deposition process over the entire effective region of a substrate surface while continuously moving a substrate holder 520 at a given speed. In other words, the vacuum vapor deposition apparatus may perform deposition in a continuous deposition manner that continuously perform deposition while moving the substrate.

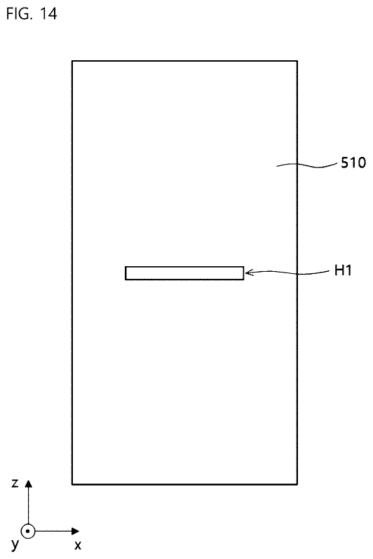

FIGS. 12 and 13 are views illustrating some enlarged components of the vacuum vapor deposition apparatus in FIG. 11. FIG. 12 is a side view along a yz plane, and FIG. 13 is a side view along an xy plane.

Referring to FIGS. 12 and 13, an opening-defining member 510, a substrate holder 520, a support member 530, and a mechanical component unit 550 are illustrated. The opening-defining member 510, the substrate holder 520, the support member 530, and the mechanical component unit 550 may form one assembly 500. A substrate S1 may be mounted on the substrate holder 520, and a source material passing through an opening H1 may be deposited on a target surface of the substrate S1. The substrate S1 may be a substrate structure in which a predetermined mask pattern (i.e., a photoresist pattern) is formed on a base substrate. The structure of the substrate S1 may be the same as or similar to that described with reference to FIGS. 1 and 2 as an example. An interval between the substrate S1 and the opening-defining member 510 may be several cm or less, for example, about 1 cm or less. It may be preferable for the interval between the substrate S1 and the opening-defining member 510 to be as small as possible.

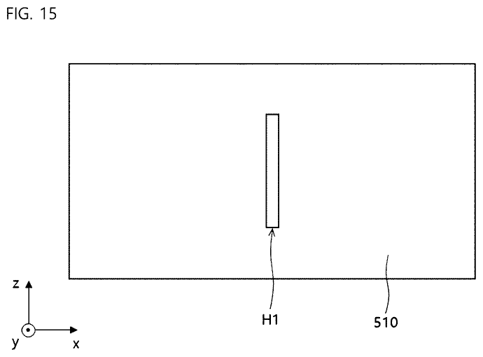

FIG. 14 is a plan view exemplarily illustrating an opening-defining member 510 applicable to the vacuum vapor deposition apparatus according to one exemplary embodiment of the present disclosure.

Referring to FIG. 14, the opening-defining member 510 may have an opening H1. The opening H1 may extend in an x-axis direction and have a length along an x-axis and a width along a z-axis. Here, the length may be greater than or equal to the width. In the case where the opening H1 has a slit shape extending in the x-axis direction, a substrate holder 520 may be configured to be linearly movable at least along a first parallel direction. In a fundamental arrangement, the first parallel direction may be a direction parallel to the z-axis. A deposition process may be performed on a substrate while moving the substrate mounted on the substrate holder 520 in the first parallel direction. The deposition process may be carried out so that a substrate surface from one end thereof to the other end thereof is exposed through the opening H1.

FIG. 15 is a plan view exemplarily illustrating an opening-defining member 510 applicable to the vacuum vapor deposition apparatus according to another exemplary embodiment of the present disclosure.

Referring to FIG. 15, the opening-defining member 510 may have an opening H1. The opening H1 may extend in a z-axis direction and have a length along the z-axis and a width along an x-axis. Here, the length may be greater than or equal to the width. In the case where the opening H1 has a slit shape extending in a z-axis direction, a substrate holder 520 may be configured to be linearly movable at least along a second parallel direction. In a fundamental arrangement, the second parallel direction may be a direction parallel to the x-axis. A deposition process may be performed on a substrate while moving the substrate mounted on a substrate holder 520 in the second parallel direction. The deposition process may be carried out so that a substrate surface from one end thereof to the other end thereof is exposed through the opening H1.

However, the shape and arrangement of the opening H1 described with reference to FIGS. 14 and 15 are exemplary and may vary depending on cases. The opening H1 may also have a square shape or any other shape. In addition, the substrate holder 520 mounted with the substrate may be configured to move in the first parallel direction and the second parallel direction. Here, the movement may include a linear reciprocating movement.

In one exemplary embodiment of the present disclosure, the opening-defining member (the screen) having the opening extending in one of the x-axis and z-axis directions is arranged in a section adjacent to the substrate between the substrate and a source emitter so that deposition is performed only through the opening, and a deposition process is performed while the substrate is moved in a direction perpendicular to an extension direction of the opening, whereby the deposition may be completed on the entire surface of the substrate.

Such a method may be useful for eliminating or maximally reducing a deviation in a length of a Josephson device or eliminating or maximally reducing a deviation in a width of the Josephson device. As described above, the deviation in width may be greater than the deviation in length, so in order to eliminate or maximally reduce the deviation in width, as exemplified in FIGS. 11 to 14, the opening-defining member provided with the slit-shaped opening extending in the x-axis direction in the section adjacent to the substrate between the substrate and the source emitter is arranged, and the deposition process may be performed while the substrate is moved in the z-axis direction.

The width of the opening may be determined in consideration of a required angular deviation, and for example, may be preferable to be between about 0.5 and 3 cm, and more preferably, may be determined to be between about 0.5 and 1.5 cm, but is not limited thereto. For example, in a case where a width of the slit-shaped opening is 1 cm, a deviation in the width of a Josephson device may be obtained as lower than about 0.5% even though this may vary depending on other conditions. Typically, one or two qubits may be designed within a 1 cm range, and in the case of a transmon, one or two Josephson junctions may be formed in the range. Accordingly, the deviation in the width of the Josephson junction formed across the entire substrate may be controlled within 0 to 0.5%.

Another advantage of one exemplary embodiment of the present disclosure is that a distance between the source emitter and the center of the substrate may be reducible due to such a small deviation.

For example, in a case where an inclined angle of the substrate is 45°, under design conditions that a thickness of a second photoresist of a Dolan process pattern is 200 nm and a width of the Josephson junction is 300 nm, the width of the Josephson junction may differ by up to about 8.3% when a distance between the source emitter and the center of the substrate is 80 cm. In a case where a distance between the source emitter and the substrate center is reduced to 50 cm or 30 cm, respective differences increase to 13.3% or 22.2%.

In contrast, in one exemplary embodiment of the present disclosure, when a width of an opening is determined as 1 cm, in a case where distances between the source emitter and the center of the substrate are given as 80 cm, 50 cm, and 30 cm, respective deviations in the width of a Josephson junction may be significantly reduced to 1.18, 0.7%, and 0.4%. Accordingly, it becomes possible to reduce the size of a vacuum chamber. For example, in a case of a chamber capable of depositing one 8-inch substrate, when a distance between a source emitter and the center of a substrate is reduced from 80 cm to 50 cm or 30 cm, respective sizes of the chamber may be reduced by 26% or 43%. Thus, this reduction in chamber size may lead to an effect of reducing the fabrication and maintenance costs in the chamber where Josephson junctions are fabricated and the maintenance of a high vacuum is required. In particular, the chamber for fabricating Josephson junctions has a property of being able to perform the metal-depositing function as well as the metal-oxidizing function at the same time, a property of being sensitive to contamination by impurities because a very thin oxide film has to be controlled, and a property of having to maintain a higher vacuum level than that of a general deposition chamber. In this respect, the effect of reducing the size of the chamber may be further enhanced.

According to one exemplary embodiment of the present disclosure, an assembly 500 in FIG. 12 is allowed to be rotated up to about 90° in a +x direction (a first rotation direction) and a −x direction (a second rotation direction) around the z-axis (the rotation axis, i.e., the rotation center), thereby enabling deposition on an inclined substrate (a wafer), i.e., angled deposition, to be performed, and also enabling the center of the opening to be aligned with the center of the source emitter. When the assembly 500 is rotated around the z-axis, the high and low sides of the substrate may be positioned symmetrically with respect to the center of the substrate.

In a case where only a portion of a vaporized source material is used by using the opening, there may be concerns about increased consumption of the source. Meanwhile, in the case of the angle evaporation process, since a distance between the substrate and the source emitter should be secured significantly, the consumption of the source may be fundamentally greater than that in the general evaporation process. In addition, considering that the thickness of a deposited material is thin (as a non-limiting example, 40 to 100 nm) and the deposited metal (as a non-limiting example, Al, etc.) is low in price, etc., the increase in the source consumption due to the use of the opening may not be a major problem. Moreover, in the case of one exemplary embodiment of the present disclosure, the distance between the source emitter and the substrate may be easily reduced. The amount of source material reaching the substrate is inversely proportional to the square of the distance, so when the distance between the substrate and the source emitter is reduced instead of utilizing the opening, the consumption of the source may be reduced and it may be advantageous in reducing equipment fabricating costs and operating costs.

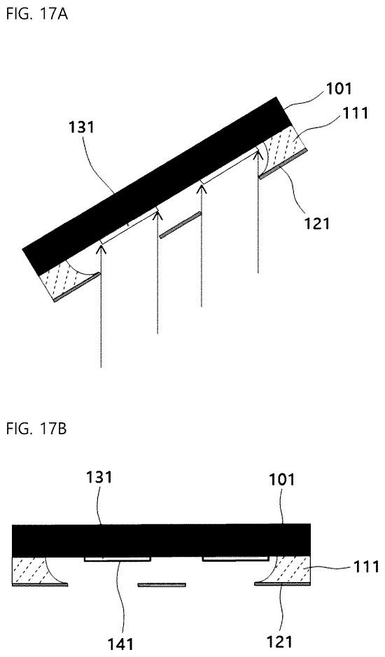

FIG. 16 is a view illustrating a vacuum vapor deposition apparatus using an evaporation method according to another exemplary embodiment of the present disclosure. The present exemplary embodiment is slightly modified from that in FIG. 11.

Referring to FIG. 16, the vacuum vapor deposition apparatus according to the present exemplary embodiment may include first and second mechanical component units 550a and 550b to which a substrate holder 520 and an opening-defining member 510 are connected or coupled. The substrate holder 520 and the opening-defining member 510 may be arranged between the first and second mechanical component units 550a and 550b. A first connection member 522 may be arranged between the substrate holder 520 and the first mechanical component unit 550a to connect them, and a second connection member 524 may be arranged between the substrate holder 520 and the second mechanical component unit 550b to connect them. The first connection member 522 and the second connection member 524 may be connected as one member. The first and second mechanical component units 550a and 550b may be configured to be able to move the substrate holder 520 along at least one of first and second parallel directions. In addition, the first and second mechanical component units 550a and 550b may be configured to be able to rotate the substrate holder 520 and the opening-defining member 510 around a z-axis. In a case where the first and second mechanical component units 550a and 550b are used, the movement and rotation of the substrate holder 520 may be more stably achieved.

According to one exemplary embodiment of the present disclosure, there may be provided a method of fabricating a device, the method including a step of depositing a material film by using the vacuum vapor deposition apparatus described above. Here, the device may include, as a non-limiting example, a Josephson device. The method of fabricating the device may include: a step of forming a first superconducting material film on a substrate while a substrate holder and an opening-defining member are rotated at a first angle condition around a z-axis; a step of forming an insulation film on a surface of the first superconducting material film; and a step of forming a second superconducting material film on an insulation film while the substrate holder and the opening-defining member are rotated around a z-axis at a second angle condition different from the first angle condition. In addition, in each of the step of forming the first superconducting material film and the step of forming the second superconducting material film, the substrate holder may be moved along at least one of first and second parallel directions.

The first and second superconducting material films may include, for example, at least one superconducting metal among Al, TiN, Nb, Ta, and V. The insulation film may be an oxide, a nitride, or any other insulating material. The oxide may be, for example, Al oxide, but is not limited thereto and may vary. In a case where the insulation film is the oxide film, the oxide film may be formed, for example, through an oxidation process on a surface part of the first superconducting material film.

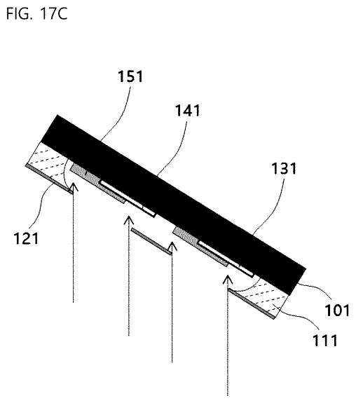

FIGS. 17A to 17C are cross-sectional views illustrating a method of fabricating a device by using a vacuum vapor deposition apparatus using an evaporation method according to one exemplary embodiment of the present disclosure.

Referring to FIG. 17A, a substrate structure may include a substrate 101 and a mask pattern arranged on the substrate 101. The mask pattern may include, for example, first and second photoresists 111 and 121. The mask pattern may be formed to have a multilayer (a dual layer) structure and an undercut structure as described in FIG. 1. Here, a “photoresist” may also be referred to as an “electron beam resist”, which may be applied equally throughout the present specification. The mask pattern may be formed, for example, by electron beam lithography or by photolithography.

A first superconducting material film 131 may be formed on the substrate 101 while rotating the substrate 101 at a first angle condition by using the vacuum vapor deposition apparatus according to one exemplary embodiment of the present disclosure. At this time, a source material may be provided to the substrate 101 through an opening, and the substrate 101 may be moved in a predetermined direction during a deposition process.

Referring to FIG. 17B, an insulation film 141 may be formed on a surface of the first superconducting material film 131. The insulation film 141 may be formed within the vacuum vapor deposition apparatus. In a case where the insulation film 141 is an oxide film, the oxide film may be formed, for example, through an oxidation process on a surface part of the first superconducting material film 131. However, the method of forming the insulation film 141 is not limited thereto and may vary depending on cases.

Referring to FIG. 17C, a second superconducting material film 151 may be formed on the substrate 101 while rotating the substrate 101 at a second angle condition by using the vacuum vapor deposition apparatus according to one exemplary embodiment. At this time, a source material may be provided to the substrate 101 through the opening, and the substrate 101 may be moved in a predetermined direction during the deposition process. The second superconducting material film 151 may be formed on the insulation film 141 and may be formed so as to partially overlap with the first superconducting material film 131. A Josephson junction may be defined in a region where the second superconducting material film 151 and the insulation film 141 are in contact.

By forming a plurality of qubits on the substrate 101 on which Josephson devices are formed by using the method exemplified in FIGS. 17A to 17C, a circuit (a qubit-based circuit) including the plurality of qubits may be fabricated. The plurality of qubits may be a plurality of superconducting qubits. The exemplary embodiments of the present disclosure may be applied to, for example, quantum computers, quantum sensors, quantum communications, superconducting devices, etc.

According to the exemplary embodiments of the present disclosure described above, it is possible to implement the vacuum vapor deposition apparatus for enabling fabrication of a device having a more accurate and precise size by reducing errors (dispersion), which occur depending on the positions of a substrate, in the fabrication of quantum technology-related devices such as Josephson devices. In addition, according to the exemplary embodiments of the present disclosure, the method of fabricating the device by using the above-described vacuum vapor deposition apparatus may be implemented.

The conventional evaporator has a fundamental limitation in that the amount of metal deposited and an incidence angle vary depending on the positions of a substrate due to the properties of a source being processed and deposited radially (partially radially) at a predetermined angle from a metal source generation unit having a relatively small cross-sectional area. Among these limitations, the problem of varying the amount of metal may be partially alleviated by the related document 1, but the bigger problem of varying the incidence angle has not been resolved at the equipment level, and the method of correcting the pattern of a substrate has been proposed in the related document 2. However, in the case of the above pattern correction method, there is a problem that a pattern size should be corrected individually according to a position of the substrate, and the correction has to be performed every time the position or size of each device changes.

According to one exemplary embodiment of the present disclosure, the vacuum vapor deposition apparatus and the related method thereof capable of drastically reducing the process error (dispersion) may be implemented by using the opening-defining member having the defined opening in the shape of the slit as the example, so as to allow the source material to pass only through the opening, and then making the incident amount and incidence angle of the source material uniform or nearly uniform over the entire effective region of the substrate while moving the position of the substrate on which the predetermined mask pattern is formed. In addition, according to one exemplary embodiment of the present disclosure, since the distance between the source emitter and the substrate may be reduced, the source overconsumption occurring when the deposition is performed only through the opening may be compensated for. In addition, as the equipment size is reduced, the effect may be obtained in which the equipment fabricating cost is reduced and the operating cost such as the vacuum maintenance cost may be reduced.

The present specification discloses the preferred exemplary embodiments of the present disclosure, and although the specific terms are used, they are used only in a general sense to easily describe the technical content of the present disclosure and to help understanding of the present disclosure, and are not intended to limit the scope of the present disclosure. In addition to the exemplary embodiments disclosed herein, it will be apparent to those skilled in the art that other modifications based on the technical idea of the present disclosure are possible. Those skilled in the art will appreciate that the vacuum vapor deposition apparatus and the method of fabricating the device using the same according to the exemplary embodiments described with reference to FIGS. 11 to 17C may be variously substituted, changed, and modified without departing from the technical spirit of the present disclosure. For example, in the vacuum vapor deposition apparatus according to the exemplary embodiments, the opening-defining member may also have two or more openings. As another example, the vacuum vapor deposition apparatus according to the exemplary embodiments may also include two or more source emitters. In addition, there are many other variations that may be applicable.

What is claimed is:

1. A vacuum vapor deposition apparatus using an evaporation method, the apparatus comprising:
a source emitter configured to emit a source material through evaporation in a vacuum chamber;
an opening-defining member configured to be spaced apart from and positioned above the source emitter in a y-axis direction within the vacuum chamber, have a surface thereof arranged parallel to an xz-plane along a z-axis and an x-axis perpendicular to the y-axis in a fundamental arrangement, and have an opening through which the source material passes, the opening having a structure extending in an x-axis direction or a z-axis direction in the fundamental arrangement; and
a substrate holder configured to be positioned spaced apart from the source emitter with the opening-defining member interposed therebetween within the vacuum chamber, and be provided with a substrate mounted thereon so as to allow a surface of the substrate on which the source material passing through the opening is deposited to face downward,
wherein the substrate holder is configured to be movable along at least one of a first parallel direction parallel to the substrate and a second parallel direction parallel to the substrate and perpendicular to the first parallel direction,
the first parallel direction is parallel to the z-axis and the second parallel direction is parallel to the x-axis in the fundamental arrangement, and
the substrate holder and the opening-defining member are configured to be rotatable around the z-axis.

2. The apparatus of claim 1, wherein a center of the source emitter and a center of the opening are arranged on a vertical line.

3. The apparatus of claim 1, wherein the substrate holder is configured to be rotatable at a controlled angle in each of a first rotational direction and a second rotational direction opposite to the first rotational direction around the z-axis.

4. The apparatus of claim 1, wherein the opening has a slit shape.

5. The apparatus of claim 1, wherein the opening is configured to extend in the x-axis direction and have a length along the x-axis and a width along the z-axis, and
the substrate holder is configured to be linearly movable along at least the first parallel direction.

6. The apparatus of claim 1, wherein the opening is configured to extend in the z-axis direction and have a length along the z-axis and a width along the x-axis, and
the substrate holder is configured to be linearly movable along at least the second parallel direction.

7. The apparatus of claim 1, wherein the opening has a length along any one of the x-axis and the z-axis and a width along the other of the x-axis and the z-axis, and
a width of the opening is in a range of 0.1 to 10 cm.

8. The apparatus of claim 1, wherein the vacuum vapor deposition apparatus is configured to variably control a width of the opening.

9. The apparatus of claim 1, wherein a center of the substrate, the center of the opening, and the center of the source emitter are arranged on a vertical line when the center of the substrate is positioned on the center of the opening.

10. The apparatus of claim 1, further comprising:
a shutter member arranged between the source emitter and the opening-defining member and configured to block or allow movement of the source material toward the opening-defining member, or control the movement in other methods.

11. The apparatus of claim 1, further comprising:
a mechanical component unit to which the substrate holder and the opening-defining member are connected or coupled,
wherein the mechanical component unit is configured to be able to move the substrate holder along at least one of the first and second parallel directions, and is configured to be able to rotate the substrate holder and the opening-defining member around the z-axis.

12. The apparatus of claim 1, further comprising:
first and second mechanical component units to which the substrate holder and the opening-defining member are connected or coupled,
wherein the substrate holder and the opening-defining member are arranged between the first and second mechanical component units, and
the first and second mechanical component units are configured to be able to move the substrate holder along at least one of the first and second parallel directions and are configured to be able to rotate the substrate holder and the opening-defining member around the z-axis.

13. The apparatus of claim 1, further comprising:
a support member configured to directly or indirectly support the substrate holder on a side opposite to a side where the opening-defining member is arranged.

14. The apparatus of claim 1, wherein the opening-defining member is configured to have a function of a gas injection unit for injecting gas into the vacuum chamber.

15. The apparatus of claim 1, wherein the vacuum vapor deposition apparatus is configured to perform a deposition process while the substrate holder is rotated by a given angle around the z-axis.

16. The apparatus of claim 1, wherein the vacuum vapor deposition apparatus is configured to perform a deposition process over an entire effective region of the substrate surface while continuously moving the substrate holder at a given speed.

17. The apparatus of claim 1, wherein the vacuum vapor deposition apparatus is configured to perform a deposition process on an entire effective region of the substrate surface in a step-and-repeat manner, so as to move the substrate holder after performing the deposition process on an N-th region of the substrate surface and perform the deposition process on an (N+1)-th region of the substrate surface in the step-and-repeat manner.

18. A method of fabricating a device, the method comprising:
depositing a material film by using a vacuum vapor deposition apparatus as described in claim 1.

19. The method of claim 18, wherein the device comprises a Josephson device.

20. The method of claim 19, further comprising:
forming a first superconducting material film on a substrate while a substrate holder and an opening-defining member are rotated at a first angle condition around a z-axis;
forming an insulation film on a surface of the first superconducting material film; and
forming a second superconducting material film on the insulation film while the substrate holder and the opening-defining member are rotated a second angle condition different from the first angle condition around the z-axis.

21. The method of claim 20, wherein in each of the forming of the first superconducting material film and the forming of the second superconducting material film, the substrate holder is moved along at least one of first and second parallel directions.
